(19) United States
(12) Patent Application Publication
(10) Pub. No.: US 2017/0318676 A1
(43) Pub. Date: Nov. 2, 2017

(54) WIRED CIRCUIT BOARD AND PRODUCING METHOD THEREOF, AND WIRED CIRCUIT BOARD ASSEMBLY AND PRODUCING METHOD THEREOF

(71) Applicant: NITTO DENKO CORPORATION, Osaka (JP)

(72) Inventors: Takahiro TAKANO, Osaka (JP); Hitoki KANAGAWA, Osaka (JP); Takatoshi SAKAKURA, Osaka (JP)

(73) Assignee: NITTO DENKO CORPORATION, Osaka (JP)

(21) Appl. No.: 15/651,467

(22) Filed: Jul. 17, 2017

Related U.S. Application Data
(62) Division of application No. 14/936,122, filed on Nov. 9, 2015.

(30) Foreign Application Priority Data
Nov. 10, 2014 (JP) 2014-227775

(51) Int. Cl. H05K 1/11; B23K 3/02; B23K 1/008; B23K 1/005; H05K 3/40; B23K 1/00; B23K 101/40

(52) U.S. Cl. CPC H05K 1/115; H05K 3/40; B23K 3/02; B23K 1/0016; B23K 1/008; B23K 1/0056; B23K 2201/40

(57) ABSTRACT

A method for producing a wired circuit board, including an insulating layer having a first through portion passing through in a thickness direction thereof and a first terminal portion having a second through portion overlapped with the first through portion when projected in the thickness direction, includes the steps of providing a first bonding material at one surface in the thickness direction of the first terminal portion and allowing the first bonding material to flow from the one surface in the thickness direction of the first terminal portion toward the other surface in the thickness direction thereof into the second through portion by allowing the first bonding material to flow.

### CROSS-REFERENCE TO RELATED APPLICATION

The present application claims priority from Japanese Patent Application No. 2014-227775 filed on Nov. 10, 2014, the contents of which are hereby incorporated by reference into this application.

### BACKGROUND OF THE INVENTION

### Field of the Invention

The present invention relates to a wired circuit board, to be specific, to a wired circuit board such as a suspension board with circuit and a producing method thereof, and a wired circuit board assembly, to be specific, to a wired circuit board assembly such as a suspension board with circuit on which an electronic component such as a piezoelectric element is mounted and a producing method thereof.

### Description of Related Art

As a wired circuit board assembly, a suspension board with circuit to which a plurality of electronic components such as a magnetic head, a power source, an external board, and a piezoelectric element are connected has been conventionally known.

As such a suspension board with circuit, a suspension board with circuit in which each terminal of the magnetic head, the power source, and the external board is disposed at one side in a thickness direction thereof and a terminal of the piezoelectric element is disposed at the other side in the thickness direction thereof has been known (ref: for example, Japanese Unexamined Patent Publication No. 2013-062013).

In the suspension board with circuit, the magnetic head, the power source, and the external board are disposed at the opposite side to the piezoelectric element with the suspension board with circuit sandwiched therebetween, and improvement in a degree of freedom in layout of the plurality of electronic components is achieved.

### SUMMARY OF THE INVENTION

In the suspension board with circuit described in the above-described Japanese Unexamined Patent Publication No. 2013-062013, each of the terminals of the magnetic head, the power source, and the external board is connected to the suspension board with circuit at the one side in the thickness direction thereof, and the terminal of the piezoelectric element is connected to the suspension board with circuit at the other side in the thickness direction thereof.

Each of the terminals of the magnetic head, the power source, the external board, and the piezoelectric element may be connected to the suspension board with circuit by a bonding material such as solder or an electrically conductive adhesive. In such a case, in the suspension board with circuit described in the above-described Patent Document 1, the bonding materials are disposed at both sides of the one side and the other side in the thickness direction thereof and thereafter, each of the terminals of the magnetic head, the power source, and the external board is disposed at the one side in the thickness direction of the suspension board with circuit, and the terminal of the piezoelectric element is disposed at the other side in the thickness direction thereof. Then, each of the terminals of the magnetic head, the power source, the external board, and the piezoelectric element is electrically connected to the suspension board with circuit.

That is, to mount the magnetic head, the power source, the external board, and the piezoelectric element so as to sandwich the suspension board with circuit therebetween, while a degree of freedom in layout is improved, the bonding materials need to be provided on both surfaces of the suspension board with circuit, so that there is a disadvantage that the operation steps are complicated.

It is an object of the present invention to provide a wired circuit board that is capable of improving a degree of freedom in layout and a producing method thereof, and a wired circuit board assembly in which a first electronic component is mounted on the wired circuit board and a producing method thereof.

The present invention [1] includes a method for producing a wired circuit board including an insulating layer having a first through portion passing through in a thickness direction thereof and a first terminal portion having a second through portion overlapped with the first through portion when projected in the thickness direction, the method including the steps of providing a first bonding material at one surface in the thickness direction of the first terminal portion and allowing the first bonding material to flow from the one surface in the thickness direction of the first terminal portion toward the other surface in the thickness direction thereof into the second through portion by allowing the first bonding material to flow.

According to the method for producing a wired circuit board, the first bonding material that is provided at the one surface in the thickness direction of the first terminal portion can flow into the second through portion to then flow toward the other surface in the thickness direction of the first terminal portion.

That is, the first bonding material that is provided at the one surface in the thickness direction of the first terminal portion faces the other side in the thickness direction, and at the other side in the thickness direction of the first terminal portion, the first terminal portion is capable of being connected to an external terminal via the first bonding material, so that improvement in a degree of freedom in layout can be achieved.

The present invention [2] further includes, in the method for producing a wired circuit board described in [1], a second terminal portion disposed at one side in the thickness direction of the insulating layer and providing a second bonding material at one surface in the thickness direction of the second terminal portion in the step of providing the first bonding material.

According to the method for producing a wired circuit board, at one side in the thickness direction of the second terminal portion, the second terminal portion is capable of being connected to an external terminal via the second bonding material that is provided at the one surface in the thickness direction of the second terminal portion.

The first bonding material and the second bonding material are provided in the same plane in the thickness direction with respect to the first terminal portion and the second terminal portion, respectively, so that the first bonding material and the second bonding material can be provided in one step.

Thus, improvement in a degree of freedom in layout can be achieved, while the first bonding material and the second bonding material can be easily formed.

The present invention [3] includes, in the method for producing a wired circuit board described in [1] or [2], the ratio of the volume of the first bonding material with respect to that of the second through portion of 100% or more.

According to the method for producing a wired circuit board, the ratio of the volume of the first bonding material with respect to that of the second through portion is 100% or more, so that the first bonding material flowing into the second through portion can surely reach the other surface in the thickness direction of the first terminal portion.

The present invention [4] includes a method for producing a wired circuit board assembly, the method including the steps of: preparing a wired circuit board according to the method for producing a wired circuit board described in any one of [1] to [3], disposing a first electronic component having a first contact so as to allow the first contact to face the other surface in a thickness direction of a first terminal portion, and electrically connecting the first terminal portion to the first contact via a first bonding material by allowing the first bonding material to flow.

According to the method for producing a wired circuit board assembly, the first electronic component is disposed so that the first contact faces the other surface in the thickness direction of the first terminal portion.

The first bonding material flows, so that it can electrically connect the first terminal portion to the first contact of the first electronic component at the other side in the thickness direction of the first terminal portion.

That is, at the other side in the thickness direction of the first terminal portion, the first terminal portion can be electrically connected to the first contact by the first bonding material that is provided at the one surface in the thickness direction of the first terminal portion.

As a result, the first electronic component can be easily mounted on the wired circuit board, while improvement in a degree of freedom in layout is achieved.

The present invention [5] includes, in the method for producing a wired circuit board assembly described in [4], the step of preparing a wired circuit board according to the method for producing a wired circuit board described in [2], of the steps of preparing the wired circuit board according to the method for producing a wired circuit board described in [1] to [3], disposing a second electronic component having a second contact so as to allow the second contact to face the one surface in the thickness direction of the second terminal portion, and electrically connecting the second terminal portion to the second contact via the second bonding material by allowing the second bonding material to flow.

According to the method for producing a wired circuit board assembly, the second electronic component is disposed so that the second contact faces the one surface in the thickness direction of the second terminal portion.

The second bonding material flows, so that it electrically connects the second terminal portion to the second contact of the second electronic component at the one side in the thickness direction of the second terminal portion.

Thus, the first electronic component can be disposed so that the first contact thereof is electrically connected at the other side in the thickness direction of the first terminal portion, and the second electronic component can be disposed so that the second contact thereof is electrically connected at the one side in the thickness direction of the second terminal portion.

As a result, the first electronic component and the second electronic component can be easily and smoothly mounted on the wired circuit board, while improvement in a degree of freedom in layout is achieved.

The present invention [6] includes a wired circuit board including an insulating layer having a first through portion passing through in a thickness direction thereof, a first terminal portion having a second through portion overlapped with the first through portion when projected in the thickness direction, and a first bonding material provided at one surface in the thickness direction of the first terminal portion and flowing from the one surface in the thickness direction of the first terminal portion toward the other surface in the thickness direction thereof into the second through portion.

According to the wired circuit board, the first bonding material that is provided at the one surface in the thickness direction of the first terminal portion can flow into the second through portion to then flow toward the other surface in the thickness direction of the first terminal portion.

That is, the first bonding material that is provided at the one surface in the thickness direction of the first terminal portion faces the other side in the thickness direction, and at the other side in the thickness direction of the first terminal portion, the first terminal portion is capable of being connected to an external terminal via the first bonding material, so that improvement in a degree of freedom in layout can be achieved.

The present invention [7] further includes, in the wired circuit board described in [6], a second terminal portion disposed at one side in the thickness direction of the insulating layer and a second bonding material provided at one surface in the thickness direction of the second terminal portion.

According to the wired circuit board, at one side in the thickness direction of the second terminal portion, the second terminal portion is capable of being connected to an external terminal via the second bonding material that is provided at the one surface in the thickness direction of the second terminal portion.

The first bonding material and the second bonding material are provided in the same plane in the thickness direction with respect to the first terminal portion and the second terminal portion, respectively, so that the first bonding material and the second bonding material can be provided in one step.

Thus, improvement in a degree of freedom in layout can be achieved, while the first bonding material and the second bonding material can be easily formed.

The present invention [8] includes a wired circuit board assembly including the wired circuit board described in [6] or [7] and a first electronic component having a first contact facing the other surface in a thickness direction of a first terminal portion and electrically connected to the first terminal portion via a first bonding material.

According to the wired circuit board assembly, the first electronic component is disposed so that the first contact faces the other surface in the thickness direction of the first terminal portion.

The first bonding material electrically connects the first terminal portion to the first contact of the first electronic component at the other side in the thickness direction of the first terminal portion.

That is, at the other side in the thickness direction of the first terminal portion, the first terminal portion can be electrically connected to the first contact by the first bonding material that is provided at the one surface in the thickness direction of the first terminal portion.

As a result, the first electronic component can be easily mounted on the wired circuit board, while improvement in a degree of freedom in layout is achieved.

The present invention [9] includes, in the wired circuit board assembly described in [8], the wired circuit board described in [7] of the wired circuit board described in [6] or [7], and a second electronic component having a second contact facing the one surface in the thickness direction of the second terminal portion and electrically connected to the second terminal portion via the second bonding material.

According to the wired circuit board assembly, the second electronic component is disposed so that the second contact faces the one surface in the thickness direction of the second terminal portion.

The second bonding material electrically connects the second terminal portion to the second contact of the second electronic component at the one side in the thickness direction of the second terminal portion.

Thus, the first electronic component can be disposed so that the first contact thereof is electrically connected at the other side in the thickness direction of the first terminal portion, and the second electronic component can be disposed so that the second contact thereof is electrically connected at the one side in the thickness direction of the second terminal portion.

As a result, the first electronic component and the second electronic component can be easily and smoothly mounted on the wired circuit board, while improvement in a degree of freedom in layout is achieved.

### BRIEF DESCRIPTION OF THE DRAWINGS

FIG. 1 shows a plan view of an assembly that is a first embodiment of a wired circuit board assembly of the present invention.

FIG. 2 shows a plan view of a gimbal portion of the assembly shown in FIG. 1.

FIG. 3 shows a sectional view along an A-A line of the gimbal portion shown in FIG. 2.

FIGS. 4A to 4D show process drawings for illustrating a method for producing an assembly:

FIG. 4A illustrating a step of preparing a metal supporting board,

FIG. 4B illustrating a step of forming a base insulating layer,

FIG. 4C illustrating a step of forming a conductive layer, and

FIG. 4D illustrating a step of forming a cover insulating layer.

FIGS. 5E to 5G, subsequent to FIG. 4D, show process drawings for illustrating a method for producing an assembly:

FIG. 5E illustrating a step of trimming a metal supporting board,

FIG. 5F illustrating a step of providing piezoelectric bonding materials in piezoelectric terminals, and

FIG. 5G illustrating a step of allowing the piezoelectric bonding materials to flow from the upper surfaces to the lower surfaces of the piezoelectric terminals.

FIGS. 6H to 6I, subsequent to FIG. 5G, show process drawings for illustrating a method for producing an assembly:

FIG. 6H illustrating a step of disposing piezoelectric elements and

FIG. 6I illustrating a step of bonding the piezoelectric terminals to piezoelectric contacts by allowing the piezoelectric bonding materials to flow.

FIG. 7A shows a sectional view of an assembly that is a second embodiment of a wired circuit board assembly of the present invention.

FIG. 7B shows a plan view of the assembly shown in FIG. 7A.

FIG. 8 shows a plan view of an assembly that is a third embodiment of a wired circuit board assembly of the present invention.

### DETAILED DESCRIPTION OF THE INVENTION

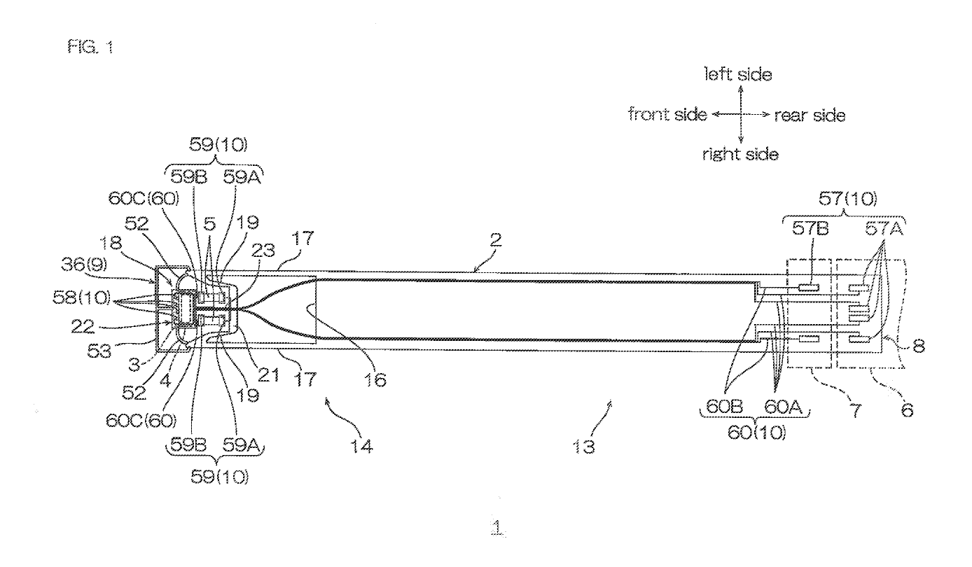

In FIG. 1, the right-left direction of the paper surface is referred to as a front-rear direction (first direction), the left side of the paper surface is referred to as a front side (one side in the first direction), and the right side of the paper surface is referred to as a rear side (the other side in the first direction). The up-down direction of the paper surface is referred to as a right-left direction (widthwise direction, second direction), the upper side of the paper surface is referred to as a left side (one side in the widthwise direction, one side in the second direction), and the lower side of the paper surface is referred to as a right side (the other side in the widthwise direction, the other side in the second direction). The paper thickness direction of the paper surface is referred to as an up-down direction (thickness direction, third direction), the near side of the paper surface is referred to as an upper side (one side in the thickness direction, one side in the third direction), and the far side of the paper surface is referred to as a lower side (the other side in the thickness direction, the other side in the third direction). To be specific, directions are in conformity with direction arrows in each view.

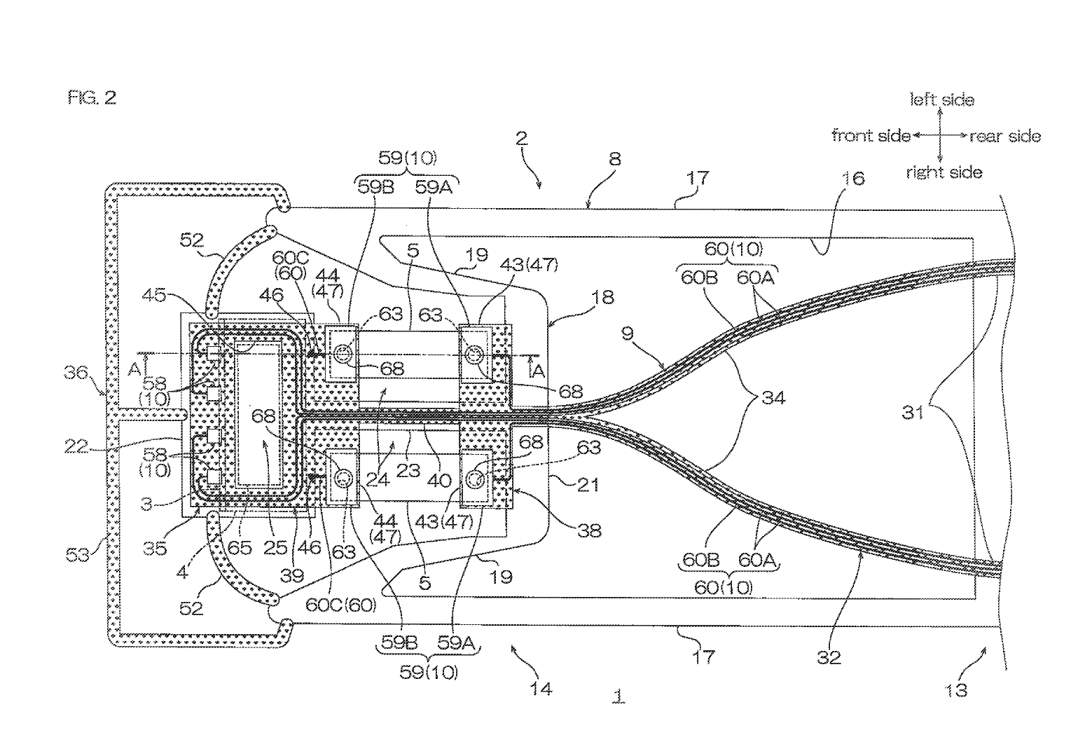

In FIG. 1, a base insulating layer 9 other than bridged portions 36 to be described later and a cover insulating layer 11 are omitted. In FIG. 2, the base insulating layer 9 is illustrated and the cover insulating layer 11 is omitted.

### First Embodiment

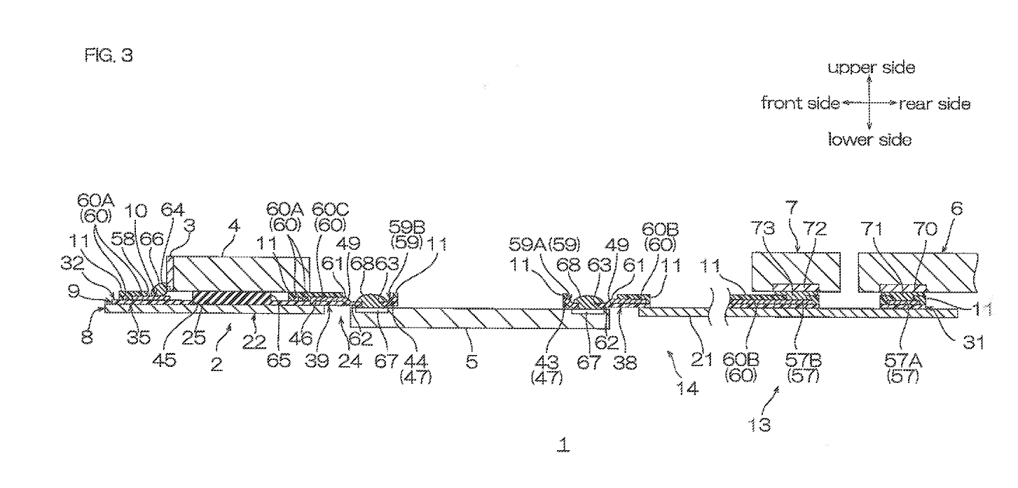

As shown in FIGS. 1 and 3, an assembly (head gimbal assembly) 1 as one example of a wired circuit board assembly is configured by mounting a slider 4 mounted with a magnetic head 3 and piezoelectric elements 5 as one example of a first electronic component on a suspension board with circuit 2 as one example of a wired circuit board, and furthermore, an external board 6 as one example of a second electronic component and a power source 7 as one example of the second electronic component are connected thereto to be then mounted on a hard disk drive (not shown).

As shown in FIG. 1, the suspension board with circuit 2 is formed into a flat belt shape extending in the front-rear direction. As shown in FIG. 3, the suspension board with circuit 2 includes a metal supporting board 8; as one example of an insulating layer, the base insulating layer 9 that is formed on the metal supporting board 8; a conductive layer 10 that is formed on the base insulating layer 9; and the cover insulating layer 11 that is formed on the base insulating layer 9 so as to cover the conductive layer 10.

As shown in FIG. 1, the metal supporting board 8 is formed into a flat belt shape extending in the front-rear direction, and integrally includes a main body portion 13 and a gimbal portion 14 that is formed at the front side of the main body portion 13.

The main body portion 13 is formed into a generally rectangular shape in plane view extending in the front-rear direction. The main body portion 13 is supported by a load beam (not shown) of a hard disk drive, when the assembly 1 is mounted on the hard disk drive.

As shown in FIG. 2, the gimbal portion 14 is formed so as to extend from the front end of the main body portion 13 forwardly.

The gimbal portion 14 includes one pair of outrigger portions 17, a mounting portion 18, and one pair of connecting portions 19.

The outrigger portions 17 are formed into slender rectangular shapes in plane view and are formed as one pair so as to extend in a linear shape from both end portions in the widthwise direction of the main body portion 13 forwardly.

The mounting portion 18 is disposed at spaced intervals to the inner side in the widthwise direction of the one pair of outrigger portions 17 and at spaced intervals in the front-rear direction to the front end edge of the main body portion 13. The mounting portion 18 is formed into a generally H-shape in plane view having an opening toward both sides in the widthwise direction. That is, both end portions in the widthwise direction of the central portion in the front-rear direction of the mounting portion 18 are cut (have an opening). To be specific, the mounting portion 18 integrally includes a base portion 21, a stage 22, and a central portion 23.

The base portion 21 is disposed at the rear end portion of the mounting portion 18 and is formed into a generally rectangular shape in plane view extending long in the widthwise direction.

The stage 22 is disposed at spaced intervals to the front side of the base portion 21 and is formed into a generally rectangular shape in plane view extending long in the widthwise direction. At the center in the widthwise direction and the center in the front-rear direction of the stage 22, a mounting region 25 on which the slider 4 is mounted is defined.

The central portion 23 is formed into a slender rectangular shape in plane view connecting the center in the widthwise direction of the base portion 21 to that in the widthwise direction of the stage 22 and extending in the front-rear direction. The central portion 23 is formed to be narrow so as to be capable of curving in the widthwise direction.

Portions that are cut in the mounting portion 18 are defined as one pair of communicating spaces 24. The one pair of communicating spaces 24 are defined at both sides in the widthwise direction of the central portion 23 and are formed so as to pass through the metal supporting board 8 in the thickness direction.

Each of the one pair of connecting portions 19 extends from each of the front end portions of the one pair of outrigger portions 17 toward both end portions in the widthwise direction of the base portion 21 to the obliquely inner rear side in the widthwise direction. In this manner, the one pair of connecting portions 19 connect the one pair of outrigger portions 17 to the mounting portion 18. Also, in this manner, a board opening portion 16 in a generally U-shape having an opening forwardly in plane view is formed between the one pair of connecting portions 19 and the one pair of outrigger portions 17, and between the mounting portion 18 and the main body portion 13.

The metal supporting board 8 is, for example, formed of a metal material such as stainless steel, 42-alloy, aluminum, copper-beryllium, and phosphor bronze. Preferably, the metal supporting board 8 is formed of stainless steel.

The metal supporting board 8 has a thickness of, for example, 5 μm or more, or preferably 10 μm or more, and, for example, 30 μm or less, or preferably 25 μm or less.

As referred to FIGS. 2 and 3, the base insulating layer 9 is formed on the upper surface of the metal supporting board 8 in a pattern corresponding to the conductive layer 10. To be specific, the base insulating layer 9 includes a main body portion insulating layer 31 corresponding to the main body portion 13 and a gimbal portion insulating layer 32 corresponding to the gimbal portion 14.

The main body portion insulating layer 31 is formed so as to correspond to the conductive layer 10 (to be specific, external terminals 57 and wires 60 to be described later) in the main body portion 13 shown in FIGS. 1 and 3.

As shown in FIG. 2, the gimbal portion insulating layer 32 includes a board opening portion insulating layer 34 corresponding to the board opening portion 16, a mounting portion insulating layer 35 corresponding to the mounting portion 18, and the bridged portions 36.

The board opening portion insulating layer 34 is formed so as to traverse the board opening portion 16 in the front-rear direction. To be specific, the board opening portion insulating layer 34 extends continuously from the front ends of both end portions in the widthwise direction of the main body portion insulating layer 31 forwardly so as to pass the board opening portion 16 and is formed into a generally Y-shape in plane view branching off toward both sides in the widthwise direction at the rear side of the board opening portion 16 to be unified at the rear side with respect to the base portion 21 and extending until the midway in the front-rear direction of the base portion 21.

The mounting portion insulating layer 35 is formed into a generally H-shape in plane view corresponding to the mounting portion 18. To be specific, the mounting portion insulating layer 35 includes a base portion insulating layer 38, a stage insulating layer 39, and a central portion insulating layer 40.

The base portion insulating layer 38 is formed corresponding to the conductive layer 10 in the base portion 21 in the mounting portion 18. The base portion insulating layer 38 is formed into a generally rectangular shape in plane view extending continuously from the board opening portion insulating layer 34 toward both outer sides in the widthwise direction at the front side of the base portion 21 in the mounting portion 18. The base portion insulating layer 38 is formed so as to extend to the front side with respect to the front end edge of the base portion 21. In the base portion insulating layer 38, portions that traverse the central portion 23 of the mounting portion 18 and are exposed from the communicating spaces 24 are defined as one pair of rear piezoelectric-side terminal forming portions 43.

The stage insulating layer 39 is formed corresponding to the conductive layer 10 in the stage 22 in the mounting portion 18. The stage insulating layer 39 is disposed at spaced intervals to the front side of the base portion insulating layer 38 and is formed into a generally rectangular shape in plane view extending from the front side of the stage 22 in the mounting portion 18 to the rear side with respect to the rear end edge of the stage 22. In the stage insulating layer 39, portions that traverse the central portion 23 of the mounting portion 18 and are exposed from the communicating spaces 24 are defined as one pair of front piezoelectric-side terminal forming portions 44. In the stage insulating layer 39, a mounting opening portion 45 corresponding to the mounting region 25 and a plurality (two pieces) of grounding opening portions 46 are formed.

As shown in FIGS. 2 and 3, the mounting opening portion 45 is formed so as to pass through the stage insulating layer 39 in the thickness direction in a generally rectangular shape to expose the mounting region 25.

The grounding opening portions 46 are, when projected in the thickness direction, formed so as to pass through the stage insulating layer 39 in the thickness direction in a portion that is overlapped with the rear end portion of the stage 22 in the mounting portion 18.

As shown in FIG. 2, the central portion insulating layer 40 is formed corresponding to the conductive layer 10 in the central portion 23 in the mounting portion 18. The central portion insulating layer 40 is formed into a slender rectangular shape in plane view connecting the center in the widthwise direction of the base portion insulating layer 38 to that in the widthwise direction of the stage insulating layer 39 and extending in the front-rear direction. The central portion insulating layer 40 is formed to be narrower than the central portion 23 and to be capable of curving in the widthwise direction.

Piezoelectric-side terminal forming portions 47 are defined as combination of the one pair of rear piezoelectric-side terminal forming portions 43 and the one pair of front piezoelectric-side terminal forming portions 44.

As shown in FIGS. 2 and 3, the piezoelectric-side terminal forming portions 47 include terminal opening portions 49 as one example of a first through portion.

One piece of terminal opening portion 49 is formed in each of the one pair of rear piezoelectric-side terminal forming portions 43 in the base portion insulating layer 38 and in each of the one pair of front piezoelectric-side terminal forming portions 44 in the stage insulating layer 39. The terminal opening portions 49 are formed so as to pass through the rear piezoelectric-side terminal forming portions 43 and the front piezoelectric-side terminal forming portions 44 in the thickness direction in generally circular shapes.

The terminal opening portion 49 has a diameter of, for example, 20 μm or more, or preferably 25 μm or more, and, for example, 500 μm or less, or preferably 400 μm or less.

As shown in FIG. 2, the bridged portions 36 include one pair of curved portions 52 that connect the front ends of the one pair of outrigger portions 17 to both ends in the widthwise direction of the stage 22 in curved shapes and an E-shaped portion 53 that connects the front ends of the one pair of outrigger portions 17 to the front end of the stage 22.

The curved portions 52 extend from the front ends of the outrigger portions 17 toward the obliquely inner front side in the widthwise direction in curved shapes to reach both ends in the widthwise direction of the stage 22.

The E-shaped portion 53 is formed into a generally E-shape in plane view. To be specific, the E-shaped portion 53 extends from the front ends of both outrigger portions 17 forwardly; then, bends inwardly in the widthwise direction and extends inwardly in the widthwise direction to be unified; and thereafter, bends rearwardly to reach the center in the widthwise direction of the front end of the stage 22.

The base insulating layer 9 is, for example, formed of an insulating material such as a synthetic resin including polyimide resin, polyamide imide resin, acrylic resin, polyether nitrile resin, polyether sulfone resin, polyethylene terephthalate resin, polyethylene naphthalate resin, and polyvinyl chloride resin. Preferably, the base insulating layer 9 is formed of polyimide resin.

The base insulating layer 9 has a thickness (maximum thickness) of, for example, 1 μm or more, or preferably 3 μm or more, and, for example, 35 μm or less, or preferably 33 μm or less.

As shown in FIG. 1, the conductive layer 10 includes the external terminals 57, head-side terminals 58, piezoelectric-side terminals 59 as one example of a first terminal portion, and the wires 60.

A plurality (six pieces) of external terminals 57 are disposed on the rear end portion of the main body portion insulating layer 31 corresponding to the main body portion 13. The external terminals 57 include signal terminals 57A as one example of a second terminal portion and power source terminals 57B.

Of the plurality (six pieces) of external terminals 57, the four pieces thereof that are disposed at the rear side are defined as the signal terminals 57A. The signal terminals 57A are disposed at spaced intervals to each other in the widthwise direction. The signal terminals 57A are electrically connected to the external board 6 via board bonding materials 71 to be described later.

Of the plurality (six pieces) of external terminals 57, the two pieces thereof that are disposed at the front side are defined as the power source terminals 57B. The power source terminals 57B are disposed at spaced intervals to each other in the widthwise direction. The power source terminals 57B are electrically connected to the power source 7 via power source bonding materials 73 to be described later.

As shown in FIG. 2, a plurality (four pieces) of head-side terminals 58 are provided on the upper surface of the front end portion of the stage insulating layer 39 corresponding to the stage 22 and are disposed at spaced intervals to each other in the widthwise direction. The head-side terminals 58 are electrically connected to the magnetic head 3 via head bonding materials 66 to be described later.

A plurality (four pieces) of piezoelectric-side terminals 59 are disposed in the piezoelectric-side terminal forming portions 47 in the base insulating layer 9 in the communicating spaces 24. To be specific, the piezoelectric-side terminals 59 are disposed in each of the one pair of rear piezoelectric-side terminal forming portions 43 in the base portion insulating layer 38 and in each of the one pair of front piezoelectric-side terminal forming portions 44 in the stage insulating layer 39. As shown in FIGS. 2 and 3, of the piezoelectric-side terminals 59, those disposed in each of the one pair of rear piezoelectric-side terminal forming portions 43 are defined as rear piezoelectric-side terminals 59A and those disposed in each of the one pair of front piezoelectric-side terminal forming portions 44 are defined as front piezoelectric-side terminals 59B. The piezoelectric-side terminal 59 has a width and a length (length in the front-rear direction) of, for example, 50 μm or more, or preferably 80 μm or more, and, for example, 800 μm or less, or preferably 500 μm or less. The piezoelectric-side terminals 59 include circumferential end portions 61, filling portions 62, and conductor opening portions 63 as one example of a second through portion.

As shown in FIG. 3, the circumferential end portions 61 are circumferential end portions of the piezoelectric-side terminals 59 and are disposed on the upper surfaces of the circumferential ends of the terminal opening portions 49 in the piezoelectric-side terminal forming portions 47.

The filling portions 62 are generally central portions in plane view of the piezoelectric-side terminals 59 and continue from the circumferential end portions 61 so as to sink in and fill the terminal opening portions 49. In this manner, the lower surfaces of the filling portions 62 are exposed from the base insulating layer 9 downwardly. The lower surfaces of the filling portions 62 are formed to be flush with the lower surface of the base insulating layer 9 that is formed at the circumferential end portions thereof in the widthwise and front-rear directions, that is, in a plane direction.

The conductor opening portions 63 are formed so as to pass through the filling portions 62 of the piezoelectric-side terminals 59 in the thickness direction in generally circular shapes. That is, the conductor opening portions 63 are, when projected in the thickness direction, formed into generally columnar shapes so as to be overlapped with the central portions of the terminal opening portions 49.

The ratio of the diameter of the conductor opening portion 63 to that of the terminal opening portion 49 is, for example, 2% or more, or preferably 5% or more, and, for example, 75% or less, or preferably 70% or less. To be specific, the conductor opening portion 63 has a diameter of, for example, 10 μm or more, or preferably 20 μm or more, and, for example, 150 μm or less, or preferably 125 μm or less.

The conductor opening portion 63 has a volume of, for example, 400 μm³ or more, or preferably 1500 μm³ or more, and, for example, 450000 μm³ or less, or preferably 300000 μm³ or less.

The piezoelectric-side terminals 59 are electrically connected to the piezoelectric elements 5 via piezoelectric bonding materials 68 to be described later.

As shown in FIG. 1, a plurality (six pieces) of wires 60 are formed at spaced intervals to each other in the widthwise direction in the main body portion insulating layer 31 (ref: FIG. 2) corresponding to the main body portion 13 and in the gimbal portion insulating layer 32 (ref: FIG. 2) corresponding to the gimbal portion 14. The wires 60 include signal wires 60A and power source wires 60B.

Of the plurality (six pieces) of wires 60, four pieces thereof at the inner side in the widthwise direction are defined as the signal wires 60A. The signal wires 60A are electrically connected to the signal terminals 57A and the head-side terminals 58. The signal wires 60A transmit electrical signals between the magnetic head 3 (ref: FIG. 3) and the external board 6 (ref: FIG. 3).

To be specific, the signal wires 60A are formed so as to extend from the signal terminals 57A forwardly at the rear end portion of the main body portion insulating layer 31 (ref: FIG. 2) corresponding to the main body portion 13 and then, as shown in FIG. 2, sequentially pass over the board opening portion insulating layer 34 and the mounting portion insulating layer 35 to reach the head-side terminals 58.

As shown in FIG. 1, of the plurality (six pieces) of wires 60, two pieces thereof at both outer sides in the widthwise direction with respect to the signal wires 60A are defined as the power source wires 60B. The power source wires 60B are electrically connected to the power source terminals 57B and the rear piezoelectric-side terminals 59A. The power source wires 60B supply electric power from the power source 7 to the piezoelectric elements 5.

To be specific, the power source wires 60B are formed so as to extend from the power source terminals 57B forwardly at the rear end portion of the main body portion insulating layer 31 (ref: FIG. 2) corresponding to the main body portion 13 and then, as shown in FIG. 2, sequentially pass the board opening portion insulating layer 34 and the mounting portion insulating layer 35 to reach the rear piezoelectric-side terminals 59A.

The wires 60 include a plurality (two pieces) of ground wires 60C that are formed at spaced intervals to each other in the widthwise direction in the gimbal portion insulating layer 32 corresponding to the gimbal portion 14.

The ground wires 60C are provided so as to ground the front piezoelectric-side terminals 59B. To be specific, as shown in FIG. 3, the ground wires 60C extend from the front piezoelectric-side terminals 59B forwardly, sink in the grounding opening portions 46 at the rear sides of the signal wires 60A, and bend downwardly so as to fill the grounding opening portions 46 to be brought into contact with the metal supporting board 8.

The conductive layer 10 is, for example, formed of a conductive material such as copper, nickel, gold, and solder or an alloy thereof. Preferably, the conductive layer 10 is formed of copper.

The conductive layer 10 has a thickness of, for example, 3 μm or more, or preferably 5 μm or more, and, for example, 50 μm or less, or preferably 20 μm or less.

Although not shown, on the surfaces of a plurality of terminals, to be specific, the external terminals 57, the head-side terminals 58, and the piezoelectric-side terminals 59, plating layers are formed, for example, by plating such as electroless plating or electrolytic plating, or preferably by electrolytic plating. The plating layers are, for example, formed of a metal material such as nickel and gold. Preferably, the plating layers are formed of gold. The plating layer has a thickness of, for example, 0.1 μm or more, or preferably 1 μm or more, and, for example, 8 μm or less, or preferably 4 μm or less.

As referred to FIG. 1, the cover insulating layer 11 is formed over the main body portion 13 and the gimbal portion 14. As shown in FIG. 3, the cover insulating layer 11 is formed on the base insulating layer 9 in a pattern including the conductive layer 10 in plane view.

To be specific, the cover insulating layer 11 is formed into a pattern covering the upper surfaces of the wires 60 and exposing the upper surfaces of the external terminals 57 (ref: FIG. 1), the head-side terminals 58, and the piezoelectric-side terminals 59.

The cover insulating layer 11 is formed of the same insulating material as that forming the base insulating layer 9. The cover insulating layer 11 has a thickness of, for example, 1 μm or more, or preferably 3 μm or more, and, for example, 40 μm or less, or preferably 10 μm or less.

The slider 4 is mounted with the magnetic head 3 that is capable of reading and writing information on a hard disk at the front end thereof and is formed into a generally rectangular box shape in plane view. At the front end of the magnetic head 3, a plurality (four pieces) of head contacts 64 are provided corresponding to the plurality of head-side terminals 58. The slider 4 is disposed in the mounting region 25 via an adhesive layer 65. The front end edge of the slider 4, that is, the magnetic head 3 is disposed along the head-side terminals 58, to be specific, formed so as to be disposed at minute spaced intervals to the upper sides of the head-side terminals 58 so that the head contacts 64 face the upper surfaces of the head-side terminals 58.

The head bonding materials 66 are provided on the upper surfaces of the head-side terminals 58.

The head bonding material 66 is, for example, formed of an electrically conductive material such as solder. Preferably, the head bonding material 66 is formed of solder having a low melting point. Examples of the solder having a low melting point include solder composed of an alloy of tin, silver, and copper; solder composed of an alloy of tin, silver, bismuth, and indium; solder composed of an alloy of tin and zinc; solder composed of an alloy of tin and bismuth; and solder composed of an alloy of tin, bismuth, and silver. The melting point of the solder having a low melting point is preferably 220° C. or less. An example of the electrically conductive adhesive includes silver paste.

The head bonding materials 66 electrically connect the head-side terminals 58 to the head contacts 64 of the magnetic head 3.

The piezoelectric elements 5 are actuators that are capable of stretching and shrinking in the front-rear direction and are formed into generally rectangular shapes in plane view extending in the front-rear direction. Electric power is supplied and the voltage thereof is controlled, so that the piezoelectric elements 5 stretch and shrink. Piezoelectric contacts 67 as one example of a first bonding material are provided in each of the front sides and the rear sides in the upper portions of the piezoelectric elements 5. As shown in FIGS. 2 and 3, the one pair of piezoelectric elements 5 are disposed at spaced intervals to each other in the widthwise direction. At this time, the piezoelectric elements 5 are disposed so as to be disposed between the rear piezoelectric-side terminals 59A and the front piezoelectric-side terminals 59B from the lower sides thereof with respect to the suspension board with circuit 2 and so that the piezoelectric contacts 67 as one example of a first contact face the lower surfaces of the piezoelectric-side terminals 59.

The piezoelectric bonding materials 68 are provided on the upper surfaces of the piezoelectric-side terminals 59.

The piezoelectric bonding material 68 is formed of the same electrically conductive material as that forming the head bonding material 66. The piezoelectric bonding materials 68 flow into the conductor opening portions 63 to extend and expand to the lower surfaces of the piezoelectric-side terminals 59, so that they electrically connect the piezoelectric-side terminals 59 to the piezoelectric contacts 67 of the piezoelectric elements 5.

As shown in FIGS. 1 and 3, the external board 6 is a flexible print circuit board and is configured to be capable of transmitting signals between a controlling portion that is not shown and the magnetic head 3. At the front end of the external board 6, a plurality (four pieces) of board contacts 70 as one example of a second contact are provided corresponding to the four pieces of signal terminals 57A. The external board 6 is disposed at minute spaced intervals to the upper sides of the signal terminals 57A so that the plurality of board contacts 70 face the upper surfaces of the respective signal terminals 57A.

The board bonding materials 71 as one example of a second bonding material are provided on the upper surfaces of the signal terminals 57A.

The board bonding material 71 is formed of the same electrically conductive material as that forming the head bonding material 66. The board bonding materials 71 electrically connect the signal terminals 57A to the board contacts 70 of the external board 6.

The power source 7 is configured to be capable of supplying electric power to the piezoelectric elements 5. At the lower end portion of the power source 7, a plurality (two pieces) of power source contacts 72 as one example of the second contact are provided corresponding to the two pieces of power source terminals 57B. The power source 7 is disposed at minute spaced intervals to the upper sides of the power source terminals 57B so that the plurality of power source contacts 72 face the upper surfaces of the respective power source terminals 57B.

The power source bonding materials 73 as one example of the second bonding material are provided on the upper surfaces of the power source terminals 57B.

The power source bonding material 73 is formed of the same electrically conductive material as that forming the head bonding material 66. The power source bonding materials 73 electrically connect the power source terminals 57B to the power source contacts 72 of the power source 7.

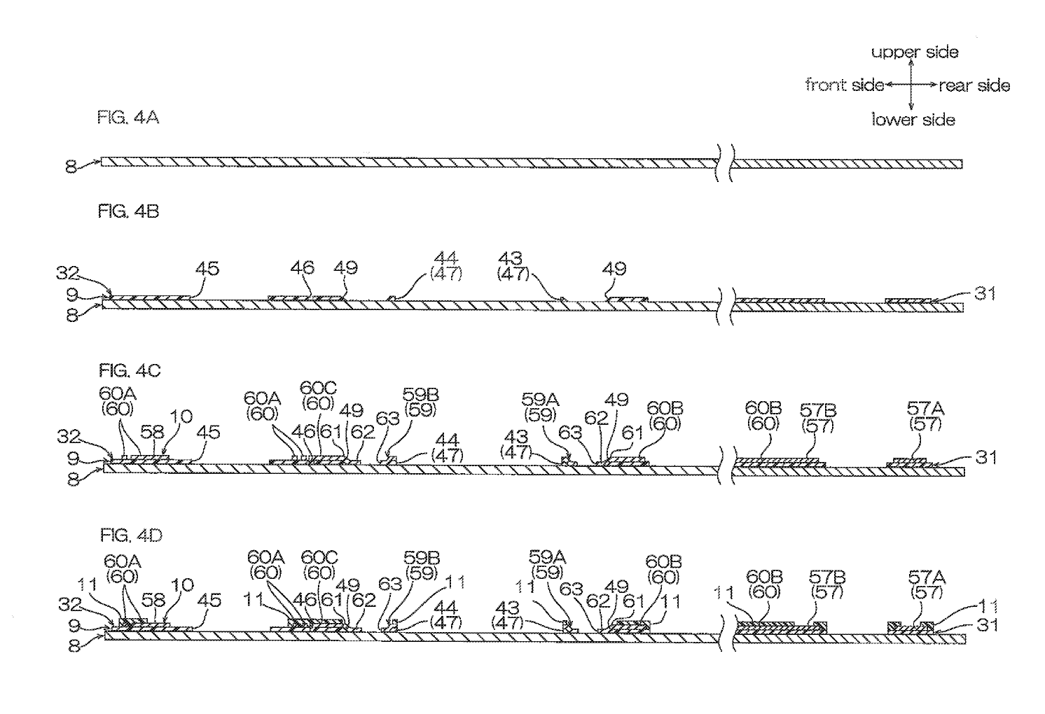

Next, a method for producing the assembly 1 is described with reference to FIGS. 4A to 61.

In this method, as shown in FIG. 4A, first, the metal supporting board 8 is prepared.

Next, as shown in FIG. 4B, the base insulating layer 9 is formed on the metal supporting board 8.

To be specific, the base insulating layer 9 is formed on the metal supporting board 8 as a pattern corresponding to the main body portion insulating layer 31 and the gimbal portion insulating layer 32. In the gimbal portion insulating layer 32, a pattern in which the grounding opening portion 46 is provided in the front piezoelectric-side terminal forming portion 44 and the terminal opening portion 49 is provided in the piezoelectric-side terminal forming portion 47 is formed.

To form the base insulating layer 9 in which the grounding opening portion 46 and the terminal opening portion 49 are formed, a varnish of an insulating material having photosensitivity is applied onto the metal supporting board 8 to be then dried, thereby forming a base film.

Thereafter, the base film is exposed to light via a photomask that is not shown. The photomask includes a light shielding portion and a light fully transmitting portion in a pattern. The light fully transmitting portion to a portion in which the base insulating layer 9 (excluding a portion in which the grounding opening portion 46 and the terminal opening portion 49 are formed) is formed and the light shielding portion to a portion in which the base insulating layer 9 is not formed and portions in which the grounding opening portion 46 and the terminal opening portion 49 are formed are disposed in opposed relation to the base film to be then exposed to light.

Thereafter, the base film is developed and is, if necessary, cured by heating, so that the base insulating layer 9 including the grounding opening portion 46 and the terminal opening portion 49 is formed in the above-described pattern.

Next, as shown in FIG. 4C, the conductive layer 10 is formed on the upper surface of the base insulating layer 9. To be more specific, the conductive layer 10 is formed on the upper surface of the base insulating layer 9 by a pattern forming method such as an additive method or a subtractive method, or preferably by an additive method.

In this manner, as referred to FIG. 1, the conductive layer 10 is formed on the upper surface of the base insulating layer 9 so as to include the external terminals 57, the head-side terminals 58, the piezoelectric-side terminals 59, and the wires 60. The piezoelectric-side terminals 59 are formed so as to fill the terminal opening portions 49, sink therein, and include the conductor opening portions 63. The end portions opposite to the front piezoelectric-side terminals 59B in the ground wires 60C are formed to sink in the grounding opening portions 46 so as to be brought into contact with the metal supporting board 8.

Next, as shown in FIG. 4D, the cover insulating layer 11 is formed on the upper surface of the base insulating layer 9. To form the cover insulating layer 11, a varnish of an insulating material having photosensitivity is applied to be then dried, thereby forming a cover film. Thereafter, the cover film is exposed to light and subsequently, developed to be cured by heating, thereby forming the cover insulating layer 11 in the above-described pattern.

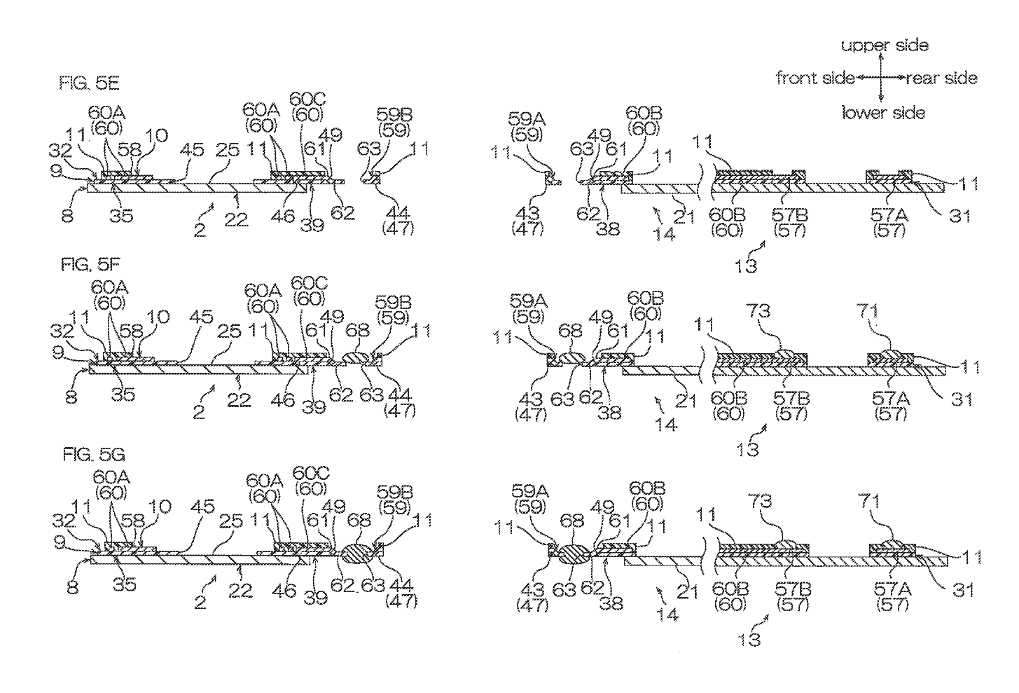

Next, as shown in FIG. 5E, the metal supporting board 8 is trimmed so as to form the board opening portion 16 by, for example, etching or the like, and to expose the lower surfaces of the rear piezoelectric-side terminal forming portions 43 and the lower surfaces of the rear piezoelectric-side terminals 59A in the base portion insulating layer 38 and to expose the lower surfaces of the front piezoelectric-side terminal forming portions 44 and the lower surfaces of the front piezoelectric-side terminals 59B in the stage insulating layer 39.

Next, as shown in FIG. 5F, the piezoelectric bonding materials 68 are formed on the upper surfaces of the piezoelectric-side terminals 59 so as to seal the conductor opening portions 63; the board bonding materials 71 are formed on the upper surfaces of the signal terminals 57A; and the power source bonding materials 73 are formed on the upper surfaces of the power source terminals 57B. To be specific, the above-described electrically conductive material is applied by printing with a known printer or with a dispenser, thereby forming the piezoelectric bonding materials 68, the board bonding materials 71, and the power source bonding materials 73.

The ratio of the volume of the piezoelectric bonding material 68 to that of the conductor opening portion 63 is, for example, 100% or more, or preferably 200% or more, and, for example, 50000% or less, or preferably 45000% or less. To be specific, the piezoelectric bonding material 68 has a volume of, for example, 2000 μm³ or more, or preferably 2500 μm³ or more, and, for example, 600000 μm³ or less, or preferably 500000 μm³ or less.

Next, as shown in FIG. 5G, the piezoelectric bonding materials 68 are melted with a reflow oven, by laser, or the like. The melting temperature at this time is more than the temperature at which the piezoelectric bonding materials 68 are melted, for example, 100° C. or more, or preferably 130° C. or more, and, for example, 350° C. or less, or preferably 300° C. or less.

In this manner, the piezoelectric bonding materials 68 are formed so as to flow from the upper surfaces of the piezoelectric-side terminals 59 to the lower surfaces thereof via the conductor opening portions 63 and to protrude toward the upper side with respect to the upper surfaces of the piezoelectric-side terminals 59 and protrude toward the lower side with respect to the lower surfaces of the piezoelectric-side terminals 59.

In the above-described manner, the suspension board with circuit 2 is produced.

The suspension board with circuit 2 obtained by the above-described producing steps, which does not include the slider 4, the piezoelectric element 5, the external board 6, and the power source 7, is a part for constituting the assembly 1 (wired circuit board assembly), that is, a part for producing the assembly 1 and is an industrially available device that is distributed alone.

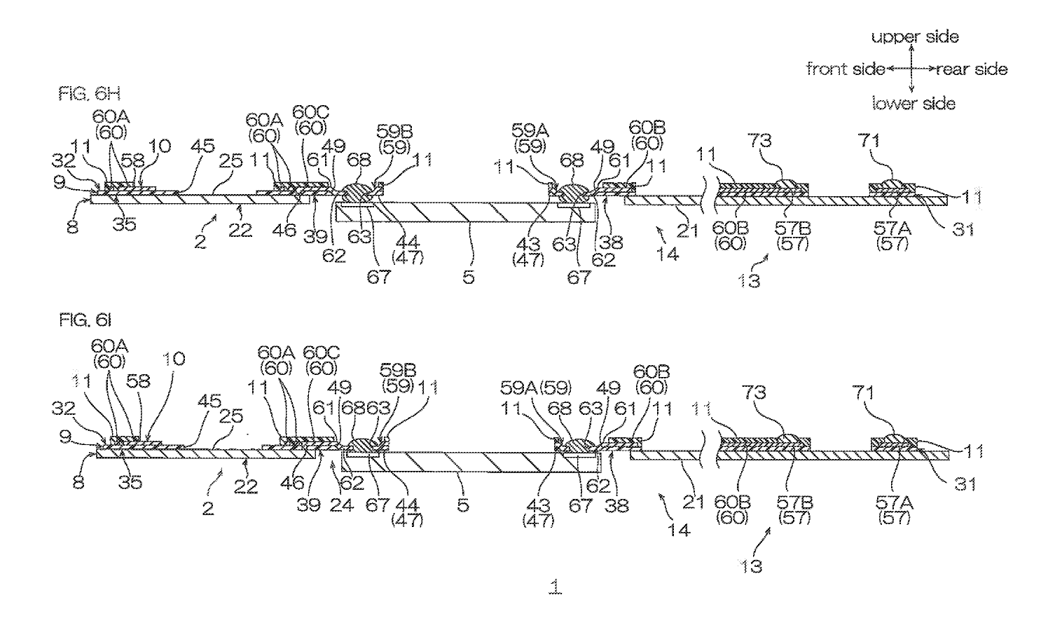

Next, as shown in FIG. 6H, the one pair of piezoelectric elements 5 are disposed at the lower side with respect to the suspension board with circuit 2 so that the piezoelectric contacts 67 are positioned at the lower sides of the respective piezoelectric-side terminals 59.

Next, the gimbal portion 14 of the suspension board with circuit 2 in which the piezoelectric elements 5 are disposed is put into a reflow oven to be then heated, so that the piezoelectric bonding materials 68 are subjected to reflow process.

The reflow temperature is more than the temperature at which the piezoelectric bonding materials 68 are melted in the same manner as that described above, for example, 100° C. or more, or preferably 130° C. or more, and, for example, 350° C. or less, or preferably 300° C. or less.

The reflow time is, for example, 5 seconds or more, or preferably 10 seconds or more, and, for example, 500 seconds or less, or preferably 300 seconds or less.

In this manner, as shown in FIG. 6I, the piezoelectric bonding materials 68 are melted to flow, so that they bond the piezoelectric-side terminals 59 to the piezoelectric contacts 67 of the piezoelectric elements 5.

Next, as shown in FIG. 3, when the slider 4 on which the magnetic head 3 is mounted is connected to the suspension board with circuit 2, first, the head bonding materials 66 are formed on the upper surfaces of the head-side terminals 58. To be specific, the above-described electrically conductive material is applied by printing with a known printer or with a dispenser, thereby forming the head bonding materials 66.

Next, the slider 4 on which the magnetic head 3 is mounted is disposed at the upper side with respect to the suspension board with circuit 2 so that the head contacts 64 are positioned at the upper sides of the head-side terminals 58.

The adhesive layer 65 is applied onto the lower surface of the slider 4 in advance, and the slider 4 is bonded to the metal supporting board 8 via the adhesive layer 65 to be mounted on the mounting region 25.

The head bonding materials 66 are heated at a temperature of more than the melting temperature thereof by a heating method such as laser (Xe lamp laser) application or soldering iron. Preferably, the head bonding materials 66 are heated by laser application.

In this manner, the head bonding materials 66 are melted to flow, so that the head-side terminals 58 are electrically connected to the head contacts 64 of the magnetic head 3.

Next, when the external board 6 is connected to the suspension board with circuit 2, the external board 6 is disposed at the upper side with respect to the suspension board with circuit 2 so that the board contacts 70 thereof are positioned at the upper sides of the signal terminals 57A.

The board bonding materials 71 are heated at a temperature of more than the melting temperature thereof by a heating method such as laser (Xe lamp laser) application or soldering iron in the same manner as that in the above-described head bonding materials 66. Preferably, the board bonding materials 71 are heated by laser application.

In this manner, the board bonding materials 71 are melted to flow, so that the signal terminals 57A are electrically connected to the board contacts 70 of the external board 6.

Also, when the power source 7 is connected to the suspension board with circuit 2, the power source 7 is disposed at the upper side with respect to the suspension board with circuit 2 so that the power source contacts 72 thereof are positioned at the upper sides of the power source terminals 57B.

The power source bonding materials 73 are heated at a temperature of more than the melting temperature thereof by a heating method such as laser (Xe lamp laser) application or soldering iron in the same manner as that in the above-described board bonding materials 71. Preferably, the power source bonding materials 73 are heated by laser application.

In this manner, the power source bonding materials 73 are melted to flow, so that the power source terminals 57B are electrically connected to the power source contacts 72 of the power source 7.

In this manner, as shown in FIGS. 1 and 3, the piezoelectric elements 5, the slider 4, the external board 6, and the power source 7 are mounted on the suspension board with circuit 2, thereby producing the assembly 1.

In the above-described steps, in the suspension board with circuit 2, the step of forming the piezoelectric bonding materials 68, the board bonding materials 71, and the power source bonding materials 73 is different from the step of forming the head bonding materials 66. However, they may be simultaneously formed.

In the above-described steps, in the suspension board with circuit 2, the piezoelectric bonding materials 68, the board bonding materials 71, and the power source bonding materials 73 are simultaneously formed. However, they may be formed in different steps. Also, for example, bonding materials in arbitrary combination only may be simultaneously formed such as a case where the piezoelectric bonding materials 68 and the board bonding materials 71 are simultaneously formed with the power source bonding materials 73 formed in a different step, or a case where the piezoelectric bonding materials 68 and the power source bonding materials 73 are simultaneously formed with the board bonding materials 71 formed in a different step.

When the slider 4 on which the magnetic head 3 is mounted is electrically connected to the head-side terminals 58, the head-side terminals 58 may be also connected to the head contacts 64 by soldering after disposing the slider 4 without providing the head bonding material 66.

In the above-described steps, after the piezoelectric bonding materials 68 that are disposed on the upper surfaces of the head-side terminals 58 are melted and are formed so as to protrude toward the lower side with respect to the lower surfaces of the piezoelectric-side terminals 59, the piezoelectric elements 5 are disposed to be subjected to reflow process. Alternatively, before the piezoelectric bonding materials 68 that are disposed on the upper surfaces of the head-side terminals 58 are melted, the piezoelectric elements 5 are disposed at the lower sides of the head-side terminals 58 to be subjected to reflow process, so that the piezoelectric bonding materials 68 flow and in this way, the piezoelectric-side terminals 59 may be also electrically connected to the piezoelectric contacts 67 of the piezoelectric elements 5.

The external board 6 and the power source 7 are electrically connected to the assembly 1 in different steps. Alternatively, the external board 6 and the power source 7 may be also connected to the assembly 1 in the same step.

According to the suspension board with circuit 2 and the producing method thereof, as shown in FIGS. 5F and 5G, the piezoelectric bonding materials 68 that are provided on the upper surfaces of the piezoelectric-side terminals 59 can flow into the conductor opening portions 63 to then flow toward the lower surfaces of the piezoelectric-side terminals 59.

That is, the piezoelectric bonding materials 68 that are provided on the upper surfaces of the piezoelectric-side terminals 59 face downwardly, and at the lower sides of the piezoelectric-side terminals 59, the piezoelectric-side terminals 59 are capable of being connected to the piezoelectric contacts 67 of the piezoelectric elements 5 via the piezoelectric bonding materials 68, so that improvement in a degree of freedom in layout can be achieved.

According to the suspension board with circuit 2 and the producing method thereof, as shown in FIGS. 3 and 6I, at the upper sides of the signal terminals 57A, the signal terminals 57A are capable of being connected to the board contacts 70 of the external board 6 via the board bonding materials 71 that are provided on the upper surfaces of the signal terminals 57A, and at the upper sides of the power source terminals 57B, the power source terminals 57B are capable of being connected to the power source contacts 72 of the power source 7 via the power source bonding materials 73 that are provided on the upper surfaces of the power source terminals 57B.

The piezoelectric bonding materials 68, the board bonding materials 71, and the power source bonding materials 73 are provided in the same plane in the up-down direction with respect to the piezoelectric-side terminals 59 and the signal terminals 57A, so that the piezoelectric bonding materials 68, the board bonding materials 71, and the power source bonding materials 73 can be provided in one step.

Thus, improvement in a degree of freedom in layout can be achieved, while the piezoelectric bonding materials 68, the board bonding materials 71, and the power source bonding materials 73 can be easily formed.

According to the method for producing the suspension board with circuit 2, as shown in FIGS. 3 and 5G, the ratio of the volume of the piezoelectric bonding material 68 with respect to that of the conductor opening portion 63 is 100% or more, so that the piezoelectric bonding materials 68 flowing into the conductor opening portions 63 can surely reach the lower surfaces of the piezoelectric-side terminals 59.

According to the assembly 1 and the producing method thereof, as shown in FIGS. 6H and 6I, the piezoelectric elements 5 are disposed so that the piezoelectric contacts 67 face the lower surfaces of the piezoelectric-side terminals 59.

The piezoelectric bonding materials 68 flow, so that they can electrically connect the piezoelectric-side terminals 59 to the piezoelectric contacts 67 of the piezoelectric elements 5 at the lower sides of the piezoelectric-side terminals 59.

That is, at the lower sides of the piezoelectric-side terminals 59, the piezoelectric-side terminals 59 can be electrically connected to the piezoelectric contacts 67 by the piezoelectric bonding materials 68 that are provided on the upper surfaces of the piezoelectric-side terminals 59.

As a result, the piezoelectric elements 5 can be easily mounted on the suspension board with circuit 2, while improvement in a degree of freedom in layout is achieved.

According to the assembly 1 and the producing method thereof, as shown in FIGS. 3 and 6H, the external board 6 is disposed so that the board contacts 70 face the upper surfaces of the signal terminals 57A, and the power source 7 is disposed so that the power source contacts 72 face the upper surfaces of the power source terminals 57B.

The board bonding materials 71 flow, so that they electrically connect the signal terminals 57A to the board contacts 70 of the external board 6 at the upper sides of the signal terminals 57A, and the power source bonding materials 73 flow, so that they electrically connect the power source terminals 57B to the power source contacts 72 of the power source 7 at the upper sides of the power source terminals 57B.

Thus, the piezoelectric elements 5 can be disposed so that the piezoelectric contacts 67 thereof are electrically connected at the lower sides of the piezoelectric-side terminals 59; the external board 6 can be disposed so that the board contacts 70 thereof are electrically connected at the upper sides of the signal terminals 57A; and furthermore, the power source 7 can be disposed so that the power source contacts 72 thereof are electrically connected at the upper sides of the power source terminals 57B.

As a result, the piezoelectric elements 5, the external board 6, and the power source 7 can be easily and smoothly mounted on the suspension board with circuit 2, while improvement in a degree of freedom in layout is achieved.

### Second Embodiment

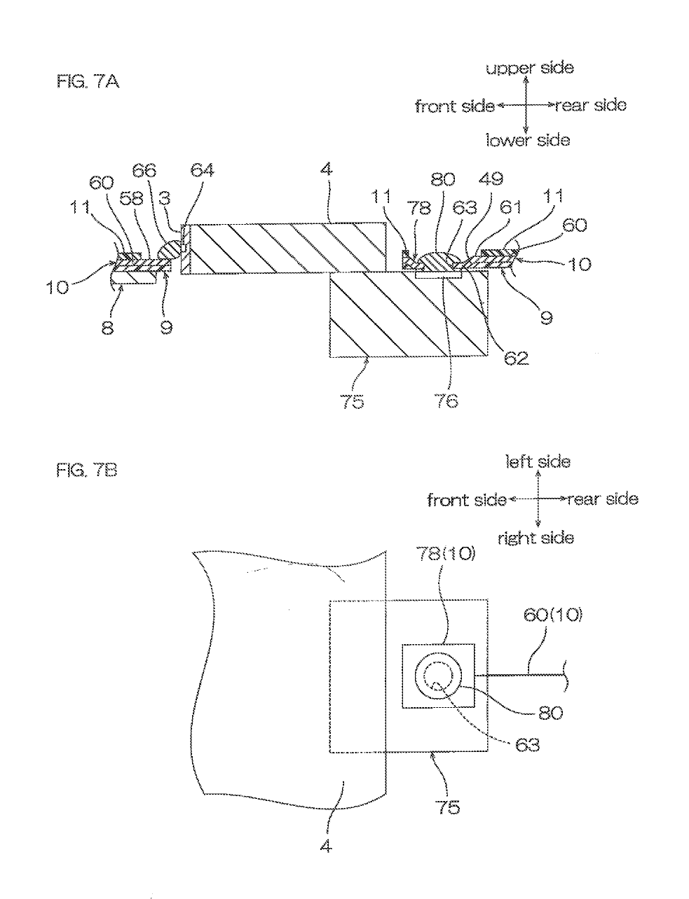

The assembly 1 of the second embodiment is described with reference to FIGS. 7A and 7B. In the second embodiment, the same reference numerals are provided for members corresponding to each of those described in the above-described first embodiment, and their detailed description is omitted.

In the above-described first embodiment, the piezoelectric element 5 is configured as one example of the first electronic component, and the external board 6 and the power source 7 are configured as one example of the second electronic component. In the second embodiment, the assembly 1 includes a light emitting element 75 as one example of the first electronic component that is integrally configured with the slider 4. The magnetic head 3 is configured as one example of the second electronic component, and the head contact 64 thereof is configured as one example of the second contact. The head bonding material 66 is configured as one example of the second bonding material.

Furthermore, in the assembly 1, the conductive layer 10 includes a light emitting element-side terminal 78 as one example of the first terminal portion. The light emitting element-side terminal 78 has the same structure as that of the piezoelectric-side terminal 59 in the above-described first embodiment. To be specific, the light emitting element-side terminal 78 includes the circumferential end portion 61, the filling portion 62, and the conductor opening portion 63.

The light emitting element 75 is formed into a generally rectangular shape in plane view that has a smaller outer shape than that of the slider 4. The light emitting element 75 is, for example, a heat assist device including a laser diode and is provided so that a recording surface of a magnetic disk that is not shown can be heated by laser beam. The upper surface of the front end portion of the light emitting element 75 is bonded to the lower surface of the rear end portion of the slider 4 and the light emitting element 75 extends toward the rear side with respect to the rear end portion of the slider 4. A light emitting terminal 76 is provided at the rear side in the upper portion of the light emitting element 75.

The light emitting element 75 is disposed at the lower side with respect to the suspension board with circuit 2, while the slider 4 is disposed so as to protrude toward the upper side with respect to the suspension board with circuit 2. The light emitting element 75 is disposed so that the light emitting terminal 76 faces the lower surface of the light emitting element-side terminal 78.

A light emitting bonding material 80 as one example of the first bonding material is provided on the upper surface of the light emitting element-side terminal 78.

The light emitting bonding material 80 is formed of the same electrically conductive material as that forming the head bonding material 66. The light emitting bonding material 80 flows into the conductor opening portion 63 to extend and expand to the lower surface of the light emitting element-side terminal 78, so that it electrically connects the light emitting element-side terminal 78 to the light emitting terminal 76 of the light emitting element 75.

To produce the assembly 1 of the second embodiment, when the metal supporting board 8 is trimmed by the same producing method as that in the above-described first embodiment, trimming is performed so as to expose the lower surface of the light emitting element-side terminal 78.

Next, the light emitting bonding material 80 is formed on the upper surface of the light emitting element-side terminal 78 so as to seal the conductor opening portion 63. The head bonding material 66 is formed on the upper surface of the head-side terminal 58.

To be specific, the above-described electrically conductive material is applied by printing with a known printer or with a dispenser, thereby forming the light emitting bonding material 80 and the head bonding material 66.

In this manner, the suspension board with circuit 2 of the second embodiment is produced.

Next, the slider 4 bonded to the light emitting element 75 is disposed on the suspension board with circuit 2. To be specific, the light emitting element 75 is disposed at the lower side with respect to the suspension board with circuit 2 so that the light emitting terminal 76 is positioned at the lower side of the light emitting element-side terminal 78, and the slider 4 is disposed so as to be positioned at the upper side with respect to the suspension board with circuit 2.

Next, the suspension board with circuit 2 in which the slider 4 bonded to the light emitting element 75 is disposed is put into a reflow oven to be then heated, so that the light emitting bonding material 80 is subjected to reflow process.

In this manner, the light emitting bonding material 80 is melted and flows to flow from the upper surface of the light emitting element-side terminal 78 into the conductor opening portion 63 and passes the same toward the lower surface of the light emitting element-side terminal 78. Then, at the lower surface of the light emitting element-side terminal 78, the light emitting bonding material 80 bonds the light emitting element-side terminal 78 to the light emitting terminal 76 of the light emitting element 75.

Next, the head bonding material 66 is heated at a temperature of more than the melting temperature thereof by a heating method such as laser (Xe lamp laser) application or soldering iron. Preferably, the head bonding material 66 is heated by laser application.

In this manner, the head bonding material 66 is melted to flow, so that the head-side terminal 58 is electrically connected to the head contact 64 of the magnetic head 3.

In this manner, the slider 4 bonded to the light emitting element 75 is mounted on the suspension board with circuit 2, thereby producing the assembly 1 of the second embodiment.

In the above-described steps, in the suspension board with circuit 2, the light emitting bonding material 80 and the head bonding material 66 are simultaneously formed. Alternatively, they may be formed in different steps.

Also, after the slider 4 bonded to the light emitting element 75 is disposed in the suspension board with circuit 2 without providing the head bonding material 66, the head-side terminal 58 may be connected to the head contact 64 of the slider 4 by soldering.

In the assembly 1 of the second embodiment, the same function and effect as that of the above-described first embodiment can be achieved.

### Third Embodiment

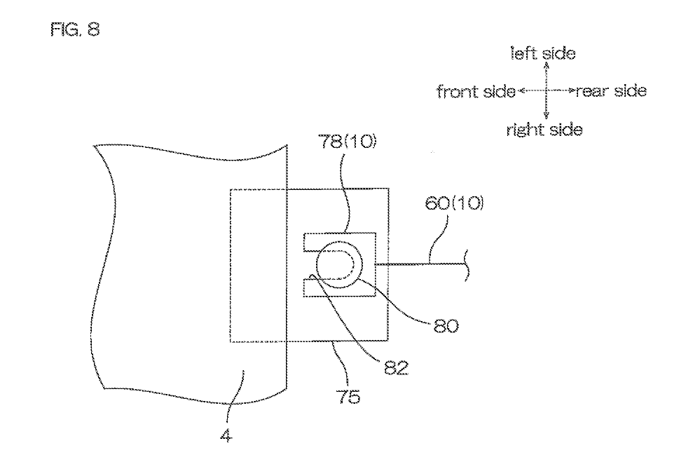

The assembly 1 of the third embodiment is described with reference to FIG. 8. In the third embodiment, the same reference numerals are provided for members corresponding to each of those described in the above-described second embodiment, and their detailed description is omitted.

In the above-described second embodiment, as referred to FIGS. 7A and 7B, the light emitting element-side terminal 78 includes, as one example of the second through portion, the conductor opening portion 63 passing through the filling portion 62 of the light emitting element-side terminal 78 in the thickness direction in a generally circular shape. In the third embodiment, the light emitting element-side terminal 78 does not include the conductor opening portion 63, and as shown in FIG. 8, includes a cut-out opening portion 82 as one example of the second through portion.

The cut-out opening portion 82 is formed into a generally U-shape in plane view that is cut from the front end portion of the light emitting element-side terminal 78 over the generally center in plane view of the light emitting element-side terminal 78.

The light emitting bonding material 80 is provided on the upper surface of the light emitting element-side terminal 78 so as to traverse the cut-out opening portion 82, and flows into the cut-out opening portion 82 to extend and expand to the lower surface of the light emitting element-side terminal 78, so that it electrically connects the light emitting element-side terminal 78 to the light emitting terminal 76 of the light emitting element 75.

To produce the assembly 1 of the third embodiment, trimming is performed so as to expose the lower surface of the light emitting element-side terminal 78 by the same producing method as that in the above-described second embodiment.

Next, the light emitting bonding material 80 is formed on the upper surface of the light emitting element-side terminal 78 so as to seal the cut-out opening portion 82. Although not shown in FIG. 8, the head bonding material 66 is formed on the upper surface of the head-side terminal 58.

To be specific, the above-described electrically conductive material is applied by printing with a known printer or with a dispenser, thereby forming the light emitting bonding material 80 and the head bonding material 66.

In this manner, the suspension board with circuit 2 of the third embodiment is produced.

Next, the suspension board with circuit 2 in which the slider 4 bonded to the light emitting element 75 is disposed is put into a reflow oven to be then heated, so that the light emitting bonding material 80 is subjected to reflow process.

In this manner, the light emitting bonding material 80 is melted and flows to flow from the upper surface of the light emitting element-side terminal 78 into the cut-out opening portion 82 and passes the same toward the lower surface of the light emitting element-side terminal 78. Then, at the lower surface of the light emitting element-side terminal 78, the light emitting bonding material 80 bonds the light emitting element-side terminal 78 to the light emitting terminal 76 of the light emitting element 75.

In the suspension board with circuit 2, though not shown in FIG. 8, by a heating method such as laser (Xe lamp laser) application or soldering iron, the head bonding material 66 is melted to flow, so that the head-side terminal 58 is electrically connected to the head contact 64 of the magnetic head 3.

In this manner, the slider 4 bonded to the light emitting element 75 is mounted on the suspension board with circuit 2, thereby producing the assembly 1 of the third embodiment.

In the above-described steps, in the suspension board with circuit 2, the light emitting bonding material 80 and the head bonding material 66 are simultaneously formed. Alternatively, they may be formed in different steps.

Also, after the slider 4 bonded to the light emitting element 75 is disposed in the suspension board with circuit 2 without providing the head bonding material 66, the head-side terminal 58 may be connected to the head contact 64 of the slider 4 by soldering.

According to the third embodiment, when the light emitting bonding material 80 is subjected to reflow process, the light emitting bonding material 80 can be melted so as to extend from the central portion of the light emitting element-side terminal 78 forwardly along the cut-out opening portion 82, so that the contact area with the light emitting terminal 76 of the light emitting element 75 can be increased, and the light emitting element-side terminal 78 can be surely electrically connected to the light emitting terminal 76 of the light emitting element 75.

In the third embodiment, the same function and effect as that of the above-described second embodiment can be achieved.

### Modified Example

The shape of the conductor opening portion 63 is not limited to a generally circular shape and can be also, for example, formed into a generally rectangular shape or a generally triangular shape.

The first bonding material and the second bonding material are not limited to solder that is melted by heating and may be formed from an electrically conductive material such as an electrically conductive adhesive that is viscous and cured by heating. In the above-described first embodiment, for example, when the head bonding material 66 and the piezoelectric bonding material 68 that are prepared from an electrically conductive adhesive are used, first, the slider 4 and the piezoelectric element 5 are disposed in the suspension board with circuit 2. Next, the head bonding material 66 is applied so that the head-side terminal 58 is bonded to the head contact 64 of the magnetic head 3. The piezoelectric bonding material 68 is applied so as to flow from the upper surface of the piezoelectric-side terminal 59 into the conductor opening portion 63 to pass the same toward the lower surface of the piezoelectric-side terminal 59 and so that at the lower surface of the piezoelectric-side terminal 59, it bonds the piezoelectric-side terminal 59 to the piezoelectric contact 67 of the piezoelectric element 5. The head bonding material 66 and the piezoelectric bonding material 68 are cured by heating, so that the assembly 1 can be also produced.

In the wired circuit board assembly of the present invention, the suspension board with circuit is described as the wired circuit board. However, the wired circuit board of the present invention is not limited to the suspension board with circuit and includes a flexible print circuit board (FPC) composed of a base layer, a conductive pattern, and a cover layer.

While the illustrative embodiments of the present invention are provided in the above description, such is for illustrative purpose only and it is not to be construed as limiting the scope of the present invention. Modification and variation of the present invention that will be obvious to those skilled in the art is to be covered by the following claims.

1. A method for producing a wired circuit board, including an insulating layer having a first through portion passing through in a thickness direction thereof and a first terminal portion having a second through portion overlapped with the first through portion when projected in the thickness direction, comprising the steps of:
providing a first bonding material at one surface in the thickness direction of the first terminal portion, and
allowing the first bonding material to flow from the one surface in the thickness direction of the first terminal portion toward the other surface in the thickness direction thereof into the second through portion by allowing the first bonding material to flow.

2. The method for producing a wired circuit board according to claim 1,
wherein a second terminal portion is disposed at one side in the thickness direction of the insulating layer, and
wherein a second bonding material is provided at one surface in the thickness direction of the second terminal portion in the step of providing the first bonding material.

3. The method for producing a wired circuit board according to claim 1, wherein
the ratio of the volume of the first bonding material with respect to that of the second through portion is 100% or more.

4. A method for producing a wired circuit board assembly comprising the steps of:
preparing a wired circuit board including an insulating layer having a first through portion passing through in a thickness direction thereof and a first terminal portion having a second through portion overlapped with the first through portion when projected in the thickness direction, comprising the steps of:
providing a first bonding material at one surface in the thickness direction of the first terminal portion,
allowing the first bonding material to flow from the one surface in the thickness direction of the first terminal portion toward the other surface in the thickness direction thereof into the second through portion by allowing the first bonding material to flow,
disposing a first electronic component having a first contact so as to allow the first contact to face the other surface in a thickness direction of a first terminal portion, and
electrically connecting the first terminal portion to the first contact via a first bonding material by allowing the first bonding material to flow.

5. The method for producing a wired circuit board assembly according to claim 4, wherein
the step of preparing a wired circuit board further includes the steps of:
disposing a second terminal portion at one side in the thickness direction of the insulating layer, and
providing a second bonding material at one surface in the thickness direction of the second terminal portion in the step of providing the first bonding material,
disposing a second electronic component having a second contact so as to allow the second contact to face the one surface in the thickness direction of the second terminal portion, and
electrically connecting the second terminal portion to the second contact via the second bonding material by allowing the second bonding material to flow.

6.-9. (canceled)
